(19) United States
(12) Patent Application Publication
(10) Pub. No.: US 2005/0147149 A1
(43) Pub. Date: Jul. 7, 2005

(54) Semiconductor laser device

(75) Inventor: Kazuyoshi Fuse, Fukaya-shi (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/012,869

(22) Filed: Dec. 16, 2004

(30) Foreign Application Priority Data
Dec. 26, 2003 (JP) 2003-433275

(51) Int. Cl. H01S 5/00; H01S 3/08

(52) U.S. Cl. 372/101; 372/107

(57) ABSTRACT

A semiconductor laser device including a semiconductor laser, a collimate lens placed opposite a light exit facet of the semiconductor laser, and a base on which the semiconductor laser is mounted, from which sleeve portions projects in a direction in which laser light is emitted, the sleeve portions being formed at respective ends of the base to hold the collimate lens. A notch is formed in each of opposite surfaces of the sleeve portions.

### CROSS-REFERENCE TO RELATED APPLICATIONS

This application is based upon and claims the benefit of priority from prior Japanese Patent Application No. 2003-433275, filed Dec. 26, 2003, the entire contents of which are incorporated herein by reference.

### BACKGROUND OF THE INVENTION

1. Field of the Invention

The present invention relates to a semiconductor laser device, and in particular, to a semiconductor laser device comprising a rod lens or cylindrical les that collimates laser light emitted by a semiconductor laser.

2. Description of the Related Art

Laser light emitted by a semiconductor laser (laser diode: hereinafter referred to as an LD), particularly a high-power LD, has a large spread angle in a direction perpendicular to an active layer. Accordingly, a rod lens or a cylindrical lens is placed near a light exit facet of the LD to collimate the light emitted by the LD. The light is thus efficiently coupled to the succeeding optical element.

Jpn. Pat. Appln. KOKAI Publication No. 2000-98190 discloses an example of such a technique. This document describes a technique for using a base on which an LD and rod lenses are mounted and bonding the rod lenses to the respective exit facets of two convex portions provided on the respective sides of the LD to collimate light emitted by the LD. The rod lenses are provided in proximity to the LD and on a side of the LD from which light is emitted. A light exit facet of the LD is parallel to the central axis of the rod lenses. An adhesive is applied to the cylindrical surfaces of opposite ends of each rod lens. The rod lenses are thus bonded to the respective end surfaces of the base which are located on the corresponding sides of the LD.

According to Jpn. Appln. KOKAI Publication No. 2000-98190, if the thickness of the adhesive, which fixes the rod lenses, is changed by a change in ambient temperature, the rod lenses move in the direction of the optical axis of laser light. This changes the distance between each rod lens and the light exit facet of the LD. The change in distance may significantly degrade collimate performance. Further, the light exit facet and the surface to which each rod lens is fixed are located on the same side of the rod lens. Moreover, the gap between the end surface of the base, including the surface to which each rod lens is fixed, and the rod lens is narrow over the length of the rod lens. The gap is located in proximity to the gap between the rod lens and the light exit facet of the LD. Consequently, when the rod lens is fixed using the adhesive, a capillary phenomenon may cause the adhesive to enter the gap between the light exit facet and the rod lens via the fine gap between the end surface of the base and the rod lens. When the adhesive thus infiltrates between the LD and the rod lens to close the light exit facet of the LD, the collimate performance of the rod lens is significantly degraded.

### BRIEF SUMMARY OF THE INVENTION

A semiconductor laser device according to the present invention comprises a semiconductor laser, a collimate lens placed opposite a light exit facet of the semiconductor laser, and a base on which the semiconductor laser is mounted, from which sleeve portions projects in a direction in which laser light is emitted, the sleeve portions being formed at respective ends of the base to hold the collimate lens, at least two notches being formed in a side surface of the base which is closer to the collimate lens, and located between the two sleeve portions.

When the collimate lens is fixed to the base, the adhesive is prevented from infiltrating between the LD and the collimate lens, thus enabling the semiconductor laser device to be manufactured with a high yield. It is further possible to suppress a variation in the position of the collimate lens and thus the degradation of collimate performance.

The advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1A is a schematic perspective view of the configuration of a semiconductor laser device showing a first embodiment of the present invention;

FIG. 1B is a sectional view taken along a YZ direction and including an LD 12 of the semiconductor laser device shown in FIG. 1A;

FIG. 1C is a diagram showing a cylindrical lens that can be used as a collimate lens;

FIG. 2A is a plan view of a semiconductor laser device according to a second embodiment of the present invention;

FIG. 2B is a sectional view taken along the YZ direction and including the LD 12 of the semiconductor laser device shown in FIG. 2A;

FIG. 3 is a plan view of a semiconductor laser device according to a third embodiment of the present invention;

FIG. 4 is a plan view of a semiconductor laser device according to a variation of the third embodiment of the present invention; and

FIG. 5 is a plan view of a semiconductor laser device according to a fourth embodiment of the present invention.

### DETAILED DESCRIPTION OF THE INVENTION

A first embodiment of the preset invention will be described below with reference to the drawings.

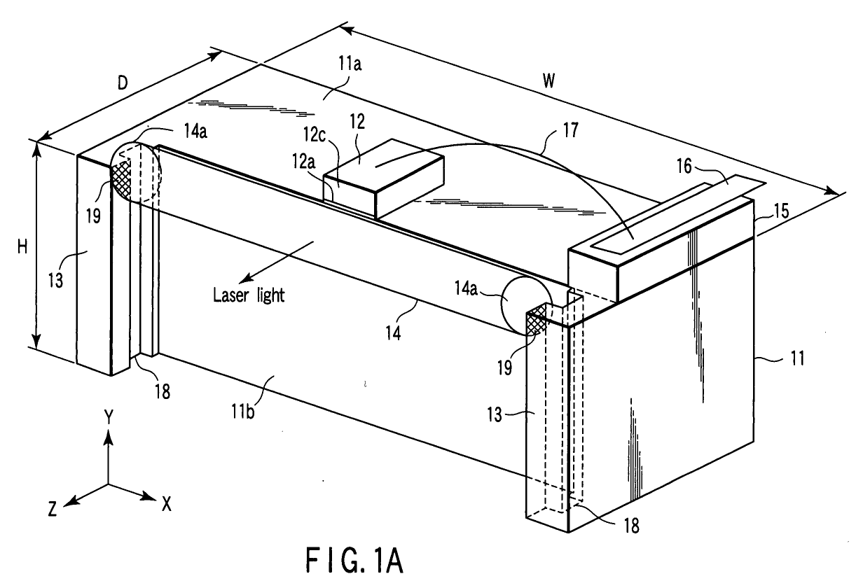

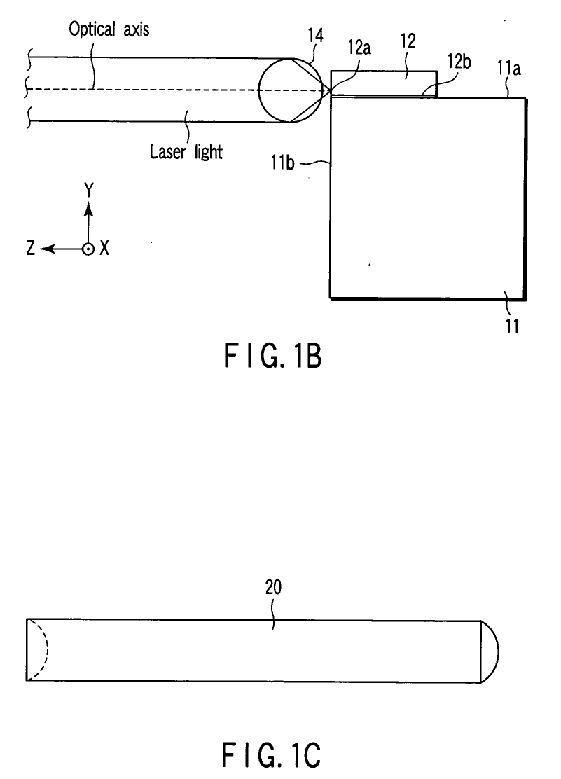

FIG. 1A is a perspective view schematically showing the configuration of a semiconductor laser device according to the present embodiment. An LD (Laser Diode) 12 is, for example, a GaAs-containing semiconductor laser and is mounted on a base 11 consisting of copper and serving as a heat sink. The base 11 has, for example, a width W of about 5 mm, a height H of about 5 mm, and a depth D of about 3 mm. As shown in the figure, a direction in which laser light is emitted corresponds to a Z axis. A vertical direction of the LD 12 corresponds to a Y axis. A horizontal direction of the LD 12 corresponds to an X axis. FIG. 1B is a sectional view taken along a YZ direction and including the LD.

A nonconductive insulating block 15 formed of ceramics or the like is mounted on one end of a surface 11a of the base 11 on which the LD 12 is mounted. A terminal 16 is placed on a top surface of the insulating block 15 so as to be connected to an external power source (not shown). An electrode (not shown) provided on a top surface of the LD is connected to the terminal 16 via a wire 17 consisting of gold. The LD 12 is connected to the external power source via the terminal 16. Further, an electrode 12b (see FIG. 1B) provided on a bottom surface (located opposite the base 11) of the LD 12 is joined by soldering or the like to the top surface of the base 11. The electrode 12b is connected to the external power source via the base 11.

The LD 12 is thus mounted on the base 11 in a junction down manner. An active layer 12a from which laser light is emitted is located in proximity to the base 11 via the solder layer. A rod lens 14 is placed opposite a light exit facet 12c of the LD 12. The rod lens 14 collimates laser light emitted in a Z direction while spreading in a Y direction. Further, the rod lens 14 is placed in proximity to the active layer 12a of the LD 12 so that the optical axis of the LD 12 passes through the center of the rod lens 14 in the direction of the Y axis.

Sleeve portions 13 are formed at the respective ends of the base 11 in the X direction. The sleeve portions 13 project in the direction in which laser light is emitted (Z direction). The sleeve portions 13 sandwich the rod lens 14 between them via an adhesive 19. The adhesive 19 is, for example, of an ultraviolet curing type. The gap between the rod lens 14 and the base 11 is very small. Accordingly, if the adhesive 19 is applied to a facet 13a of the rod lens 14 which is further from the LD 12, the capillary phenomenon may cause the adhesive, which has not been cured yet, to reach the LD 12. Thus, in the present embodiment, a notch 18 is formed in each of the opposite surfaces of the sleeve portions 13. Accordingly, the adhesive, which otherwise reaches the LD 12, is collected in the notches 18.

The ultraviolet curing adhesive 19 is applied to ends 14a of the rod lens 14 before the rod lens 14 is inserted between the sleeve portions 13. Alternatively, the rod lens 14 may be inserted between the sleeve portions 13 before the ultraviolet curing adhesive 19 is applied to between each of the ends 14a and the corresponding sleeve portion 13. Subsequently, the position of the rod lens 14 is finely adjusted. The adhesive 19 is then irradiated with ultraviolet rays to fix the rod lens 14 to the base 11.

In this embodiment, the cylindrical rod lens is described as an example of a collimate lens. However, the lens provided opposite the light exit facet 12c of the LD is not limited to the cylindrical rod lens. Another collimate lens such as a cylindrical lens 20 shown in FIG. 1C is applicable provided that the lens can collimate laser light emitted by the LD.

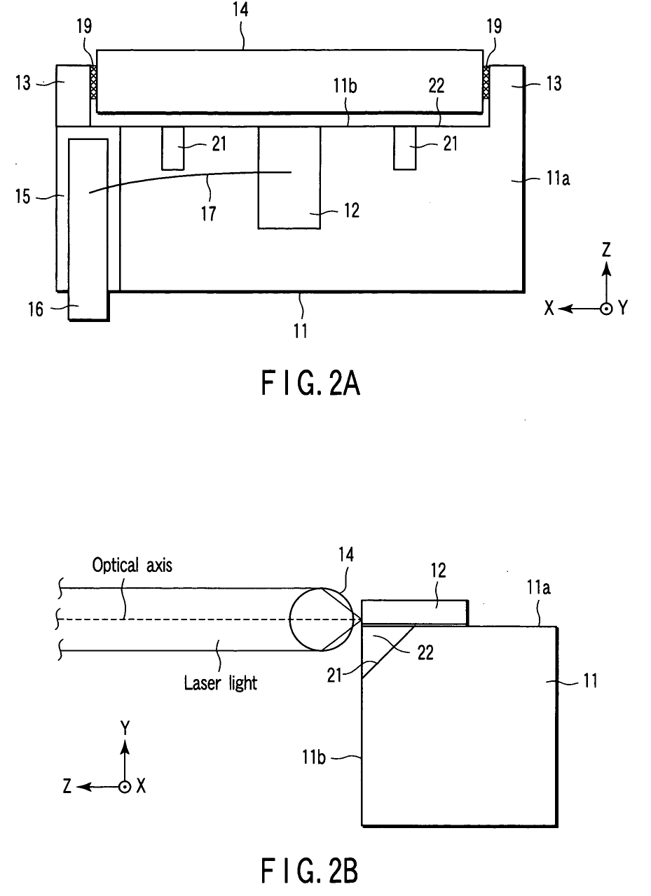

FIG. 2A is a plan view of a semiconductor laser device illustrating a second embodiment of the present invention. Here, the same components as those shown in FIG. 1 are denoted by the same reference numerals.

The second embodiment has basically the same configuration as the first embodiment except for the positions of the notches provided to prevent the entry of the adhesive. At least two notches 21 are formed on a side 11b of the base 11 which is closer to the collimate lens, and located between the two sleeve portions. In the present embodiment, the two notches 21 are formed in a ridge 22 formed by the side 11b of the base 11 located between the two sleeve portions 13 and located closer to the rod lens 14, and the surface 11a of the base 11 on which the LD 12 is mounted. Accordingly, as in the case of the first embodiment, the adhesive, which has not been cured yet and which otherwise reaches the LD 12, is collected in the notches 21.

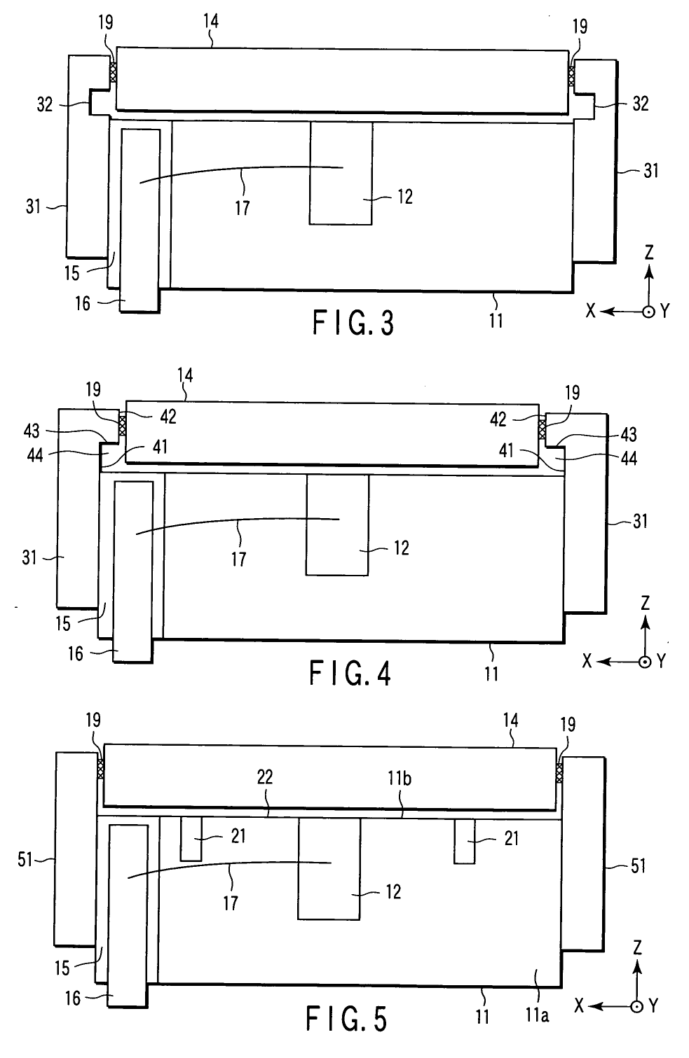

FIG. 3 is a plan view of a semiconductor laser device illustrating a third embodiment of the present invention. In the first embodiment, the sleeve portions 13, sandwiching the rod lens 14 between them, are formed integrally with the base 11. However, in the third embodiment, holding members 31 provided separately from the base 11 are fixed to the base 11 as sleeve portions. A notch 32 is formed in each of the opposite surfaces of the holding members 31. When an adhesive is used to bond the rod lens 14 and the holding members 31 together, an extra adhesive that has not been cured yet is collected in the notches 32. The adhesive is of an ultraviolet curing type. Accordingly, the holding members 31 are desirably composed of a material such as glass which is very transparent.

Alternatively, as shown in FIG. 4, the holding members 31 may be L-shaped so that a step 43 is formed between a surface of each holding member 31 which is fixed to the base 11 and a surface of the holding member 31 which holds the rod lens 14. Then, a space 44 created at the step 43 may be used as a notch for preventing the entry of the adhesive.

FIG. 5 is a plan view of a semiconductor laser device illustrating a fourth embodiment of the present invention.

In the fourth embodiment, the sleeve portions 13, formed integrally with the base 11 according to the second embodiment, are provided separately from the base 11 as holding members 51. At least two notches 21 are formed in the side 11b of the base 11 located between the holding members 51 and located closer to the rod lens. In the present embodiment, the two notches 21 are formed in the ridge 22, formed by the side 11b of the base 11 which is located closer to the rod lens and the surface 11a of the base 11 on which the LD 12 is mounted. Since the notches for preventing the entry of the adhesive are formed in the base 11, the holding members 51 need not be provided with any notches for preventing the entry of the adhesive.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor laser device comprising:
a semiconductor laser;
a collimate lens placed opposite a light exit facet of the semiconductor laser; and
a base on which the semiconductor laser is mounted, from which sleeve portions projects in a direction in which laser light is emitted, the sleeve portions being formed at respective ends of the base to hold the collimate lens,
a notch being formed in each of opposite surfaces of the sleeve portions.

2. A semiconductor laser device comprising:
a semiconductor laser;
a collimate lens placed opposite a light exit facet of the semiconductor laser; and
a base on which the semiconductor laser is mounted, from which sleeve portions projects in a direction in which laser light is emitted, the sleeve portions being formed at respective ends of the base to hold the collimate lens,
at least two notches being formed in a side surface of the base which is closer to the collimate lens, and located between the two sleeve portions.

3. The semiconductor laser device according to claim 2, wherein the two notches are formed in a ridge formed by the side surface of the base located closer to the collimate lens and the surface of the base on which the semiconductor laser is mounted.

4. A semiconductor laser device comprising:
a semiconductor laser;
a base on which the semiconductor laser is mounted;
a collimate lens placed opposite a light exit facet of the semiconductor laser; and
two holding members provided on the base to hold the collimate lens,
a notch being formed in a part of each of opposite surfaces of the holding members.

5. A semiconductor laser device comprising:
a semiconductor laser;
a base on which the semiconductor laser is mounted;
a collimate lens placed opposite a light exit facet of the semiconductor laser; and
two holding members provided on the base to hold the collimate lens,
at least two notches being formed in a side surface of the base which is closer to the collimate lens, and being located between the two holding members.

6. The semiconductor laser device according to claim 5, wherein the two notches are formed in a ridge formed by the side surface of the base located closer to the collimate lens and the surface of the base on which the semiconductor laser is mounted.

7. The semiconductor laser device according to claim 1, wherein the collimate lens is one of a rod lens and a cylindrical lens.

8. The semiconductor laser device according to claim 2, wherein the collimate lens is one of a rod lens and a cylindrical lens.

9. The semiconductor laser device according to claim 4, wherein the collimate lens is one of a rod lens and a cylindrical lens.

10. The semiconductor laser device according to claim 5, wherein the collimate lens is one of a rod lens and a cylindrical lens.
